(19) United States
(12) Patent Application Publication
(10) Pub. No.: US 2004/0101979 A1
(43) Pub. Date: May 27, 2004

(54) Ferroelectric resistor non-volatile memory

(76) Inventors: Sheng Teng Hsu, Camas, WA (US); Tingkai Li, Vancouver, WA (US)

Correspondence Address: David C. Ripma, Patent Counsel, Sharp Laboratories of America, Inc., 5750 NW Pacific Rim Boulevard, Camas, WA, 98607, US

(21) Appl. No.: 10/305,551

(22) Filed: Nov. 26, 2002

(51) Int. Cl. H01L 21/00; H01L 21/20

(52) U.S. Cl. 438/3; 438/384

(57) ABSTRACT

A method of fabricating a ferroelectric thin film resistor includes preparing a substrate; depositing a bottom electrode; depositing a layer of ferroelectric material; depositing a top electrode; and completing the resistor; wherein, the ferroelectric resistor is programmed using a programming voltage; and wherein the ferroelectric resistor is non-destructively read by a sensing method taken from the group of sensing methods consisting of constant voltage sensing and constant current sensing.

### RELATED APPLICATION

This Application is related to U.S. Pat. No. 6,048,738, granted Apr. 11, 2000, for Method of Making Ferroelectric Memory Cell for VLSI RAM Array.

### FIELD OF THE INVENTION

This invention is related to ferroelectric non-volatile memory devices, and specifically to a ferroelectric resistor-based memory device.

### BACKGROUND OF THE INVENTION

One-transistor one-ferroelectric capacitor (ITIC) memory cells and single transistor ferroelectric-based devices are used as memory storage devices. Although the ITIC memory is non-volatile, it is read destructive, i.e., the stored data is lost during a read operation, requiring refreshment of the cell. A read operation in a single transistor memory is non-destructive, however, because there is a relatively large field across the ferroelectric capacitor during standby conditions, there is a significant reduction in memory retention time.

S. Onishi et al, A half-micron Ferroelectric Memory Cell Technology with Stacked Capacitor Structure, IEDM, paper 34.4, p. 843, 1994, describes fabrication of a ferroelectric memory cell using dry etching of a PZT/Pt/TiN/Ti structure.

### SUMMARY OF THE INVENTION

A method of fabricating a ferroelectric thin film resistor includes preparing a substrate; depositing a bottom electrode; depositing a layer of ferroelectric material; depositing a top electrode; and completing the resistor; wherein, the ferroelectric resistor is programmed using a programming voltage; and wherein the ferroelectric resistor is non-destructively read by a sensing method taken from the group of sensing methods consisting of constant voltage sensing and constant current sensing.

It is an object of the invention to provide a ferroelectric memory resistor, which has a long retention time and is able to operate at high speed using very little power.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 depicts the charge distribution of a polarized ferroelectric resistor.

FIG. 2 depicts the I-V characteristics of a PGO resistor.

FIG. 3 depicts the hysteresis loop of the device of FIG. 2.

FIG. 4 depicts the I-V characteristics of a PZT memory resistor.

FIG. 5 depicts the hysteresis loop of the PZT memory resistor of FIG. 4.

### DETAILED DESCRIPTION OF THE PREFERRED EMBODIMENT

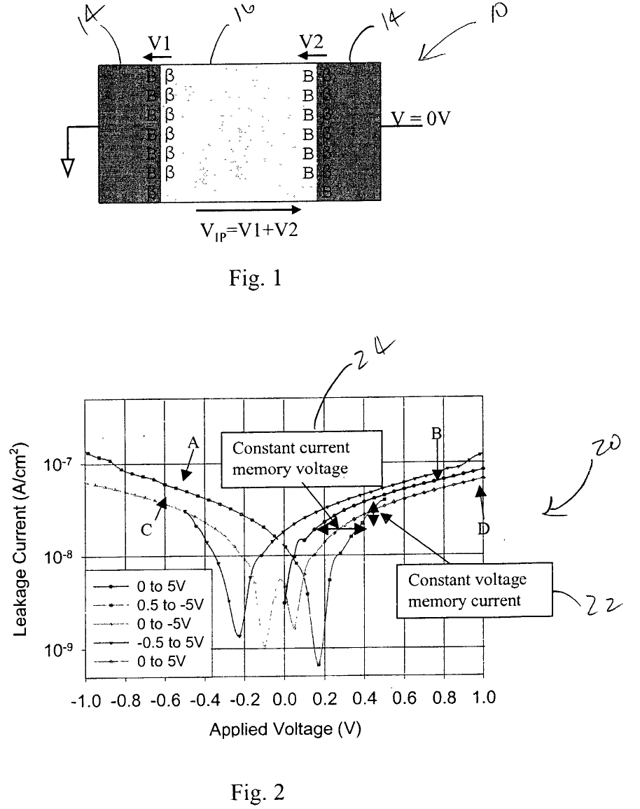

Referring now to FIG. 1, after a ferroelectric capacitor 10 is polarized, there are dipoles located at a top electrode 12 and at a bottom electrode 14, located on either side of a ferroelectric (FE) layer 16. The pairs of dipoles are associated with voltages V1 (bottom electrode) and V2 (top electrode). As the polarization of ferroelectric capacitor 10 changes, the polarity of the dipole voltage also changes. Therefore, a net change in polarization of an induced internal voltage of 2(V1+V2) occurs when capacitor 10 is programmed using +Vₚ and −Vₚ. This voltage shift creates a significant change in resistor current at a given bias voltage, as is illustrated in FIG. 2, generally at 20, which depicts-the I-V characteristics of a FE resistor fabricated using Pb₅Ge₃O₁₁ (PGO) FE material.

The programming of a ferroelectric memory resistor is the same as that of a ferroelectric memory capacitor. Curves B and D of FIG. 2 depict the I-V characteristic of the FE resistor after it is programmed with negative and positive polarization voltages, respectively. Similarly, for a negative voltage memory, curves A and C are the I-V characteristics of A FE resistor after it is programmed with a positive and negative polarization voltages, respectively. Curves A and C (or A to B) are the two memory states for negative voltage read operation. Curves B and D (or B to A) are the two memory states for positive voltage read operation.

The FE resistor memory contents may be read using a sensing method, such as a constant voltage sensing method 22 and a constant current sensing method 24, as is illustrated in FIG. 2, however, to avoid read disturbances, only low voltage and low power may be applied during the read operation. For constant voltage sensing, the sensing current difference between high and low states are shown in FIG. 2. The current difference is largest if the read voltage is about 0.1V for curve B and curve A memory states. The maximum current range is found at a voltage slightly lower than 0.2V for curve B and curve A memory states. For constant current sensing, the signal voltage is about 0.3V and the memory window is between about 0V to 1V+. These memory windows may be enlarged by proper device design. During constant voltage read operations, the read voltage is no larger than the coercive voltage of the ferroelectric thin film. Therefore, there is no de-polarization.

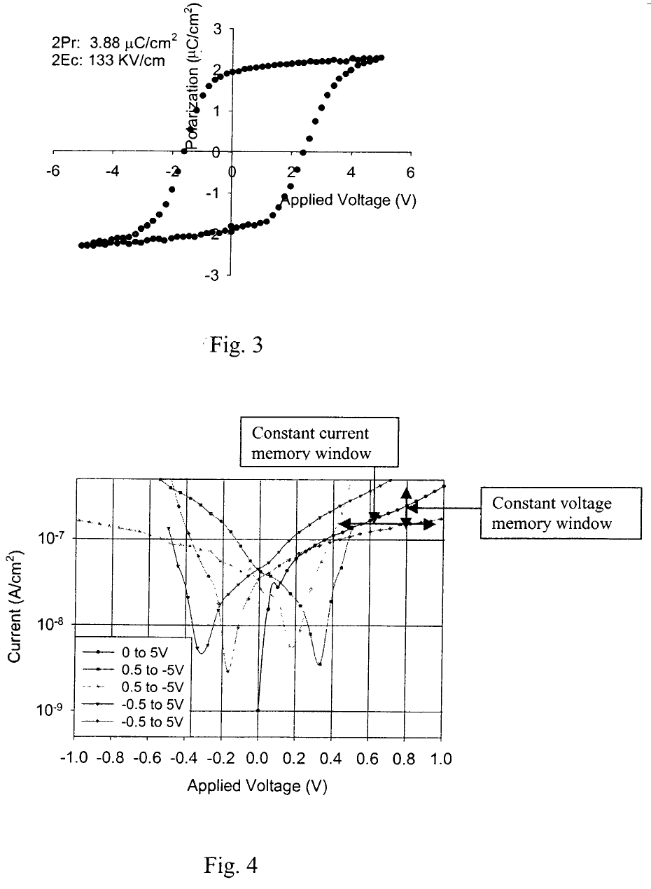

For a constant current read operation, the low voltage state is located on high current curve B, which is −Vₚ programmed. The voltage is smaller than the FE film coercive voltage. The high voltage state is located at the low current state curve D, which is +Vₚ programmed. The resistor is fully polarized, and no addition polarization is possible. Therefore, neither constant voltage nor constant current read operation disturb memory contents, and reading the memory contents of the resistor is a non-destructive operation. During standby conditions, both electrodes of the memory resistor are at the ground potential. Although there is some leakage current flow through the resistor, the memory contents of the resistor are not altered by leakage current, and a long retention time is expected. FIG. 3 depicts the hysteresis loop of the PGO device of FIG. 2.

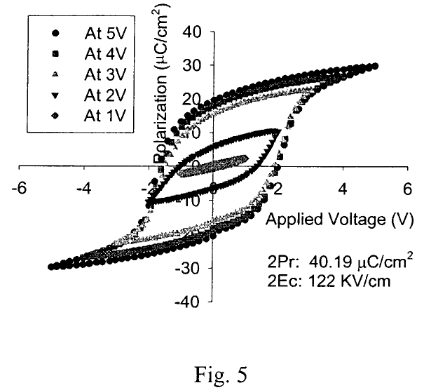

FIG. 4 and FIG. 5 depict results from typical Pb(Zr, Ti)O (PZT) devices, corresponding to the characteristics of the PGO devices in FIG. 2 and FIG. 3, respectively. A memory resistor may be fabricated using any known ferroelectric thin film material, however, because PZT ferroelectric thin film does not exhibit a clear coercive voltage, the memory retention time of a PZT FE resistor may not as long as that of PGO FE resistor.

Thus, a ferroelectric resistor non-volatile memory has been disclosed. It will be appreciated that further variations and modifications thereof may be made within the scope of the invention as defined in the appended claims.

We claim:

1. A method of fabricating a ferroelectric thin film resistor comprising:
preparing a substrate;
depositing a bottom electrode;
depositing a layer of ferroelectric material;
depositing a top electrode; and
completing the resistor;
which includes programming the ferroelectric resistor using a programming voltage; and which includes reading the ferroelectric resistor, non-destructively, by a sensing method taken from the group of sensing methods consisting of constant voltage sensing and constant current sensing.

2. The method of claim 1 wherein said depositing a layer of ferroelectric material includes depositing a layer of PGO ferroelectric material and wherein a constant voltage reading occurs at a voltage less than 0.2V.

3. The method of claim 1 wherein said depositing a layer of ferroelectric material includes depositing a layer of PGO ferroelectric material and wherein a constant current reading is read at a voltage of between about zero volts and 1+ volts.

4. The method of claim 1 wherein said depositing a layer of FE material includes depositing a layer of FE material having a defined coercive voltage, and wherein the sensing methods include setting a reading voltage which is less than or equal to the FE coercive voltage.

5. The method of claim 1 wherein said programming includes programming with a positive polarization voltage in a range of between about zero and +1 volts.

6. The method of claim 1 wherein said programming includes programming with a negative polarization voltage in a range of between about zero and −1 volts.

7. The method of claim 1 wherein said depositing a layer of FE material includes depositing a layer of FE material taken from the group of FE materials consisting of PGO and PZT.

8. A method of fabricating a ferroelectric thin film resistor comprising:
preparing a substrate;
depositing a bottom electrode;
depositing a layer of ferroelectric material having a defined coercive voltage;
depositing a top electrode; and
completing the resistor;
which includes programming the ferroelectric resistor using a programming voltage; and which includes reading the ferroelectric resistor, non-destructively, by a sensing method taken from the group of sensing methods consisting of constant voltage sensing and constant current sensing, and wherein the sensing methods include setting a reading voltage which is less than or equal to the FE coercive voltage.

9. The method of claim 8 wherein said depositing a layer of ferroelectric material includes depositing a layer of PGO ferroelectric material and wherein a constant voltage reading occurs at a voltage less than 0.2V.

10. The method of claim 8 wherein said depositing a layer of ferroelectric material includes depositing a layer of PGO ferroelectric material and wherein a constant current reading is read at a voltage of between about zero volts and 1+ volts.

11. The method of claim 8 wherein said programming includes programming with a positive polarization voltage in a range of between about zero and +1 volts.

12. The method of claim 8 wherein said programming includes programming with a negative polarization voltage in a range of between about zero and −1 volts.

13. The method of claim 8 wherein said depositing a layer of FE material includes depositing a layer of FE material taken from the group of FE materials consisting of PGO and PZT.

14. A method of fabricating a ferroelectric thin film resistor comprising:
preparing a substrate;
depositing a bottom electrode;
depositing a layer of ferroelectric material taken from the group of FE materials consisting of PGO and PZT;
depositing a top electrode; and
completing the resistor;
which includes programming the ferroelectric resistor using a programming voltage; and which includes reading the ferroelectric resistor, non-destructively, by a sensing method taken from the group of sensing methods consisting of constant voltage sensing and constant current sensing.

15. The method of claim 14 wherein said depositing a layer of ferroelectric material includes depositing a layer of PGO ferroelectric material and wherein a constant voltage reading occurs at a voltage less than 0.2V.

16. The method of claim 14 wherein said depositing a layer of ferroelectric material includes depositing a layer of PGO ferroelectric material and wherein a constant current reading is read at a voltage of between about zero volts and 1+ volts.

17. The method of claim 14 wherein said depositing a layer of FE material includes depositing a layer of FE material having a defined coercive voltage, and wherein the sensing methods include setting a reading voltage which is less than or equal to the FE coercive voltage.

18. The method of claim 14 wherein said programming includes programming with a positive polarization voltage in a range of between about zero and +1 volts.

19. The method of claim 14 wherein said programming includes programming with a negative polarization voltage in a range of between about zero and −1 volts.
